(19) United States
(12) Patent Application Publication
(10) Pub. No.: US 2009/0036312 A1
(43) Pub. Date: Feb. 5, 2009

(54) Multifilament Superconductor, as well as Method for its Production

(76) Inventors: Manfred Thoener, Biebergmuend (DE); Horst Ehser, Kahl (DE); Andreas Szulczyk, Lisengericht (DE); Alfred Auer, Bristein (DE); Vital Abaecherli, Erleinsee (DE)

Correspondence Address: BAKER BOTTS L.L.P.;PATENT DEPARTMENT, 98 SAN JACINTO BLVD., SUITE 1500, AUSTIN, TX, 78701-4039, US

(21) Appl. No.: 12/104,171

(22) Filed: Apr. 16, 2008

(30) Foreign Application Priority Data
Apr. 18, 2007 (DE) 10 2007 018 268.8

(51) Int. Cl. H01B 12/10; H01L 39/24

(52) U.S. Cl. 505/231; 505/431; 174/125.1; 29/599

(57) ABSTRACT

A multifilament superconductor (1) has a core area (2) and several superconductor filaments (4). The superconductor filaments (4) each have a core (6) made of a powder metallurgically produced superconductor. The core area (2) is enclosed by an outer shell (3) made of a non-superconducting metal or a non-superconducting alloy (8, 10). The outer shell (3) has at least one reinforcement element (9) made of tantalum or a tantalum alloy.

### CROSS-REFERENCE TO RELATED APPLICATIONS

This application claims priority to German Patent Application Number 10 2007 018 268.8 filed on Apr. 18, 2007, and which is incorporated herein by reference in its entirety.

### TECHNICAL FIELD

The invention concerns a multifilament superconductor, especially a reinforced multifilament superconductor, as well as a method for its production.

### BACKGROUND

A15 superconductors, like Nb₃Sn, can be produced by different methods in the form of a wire or strip. Known methods are the so-called bronze method, the jellyroll method, as well as the powder-in-tube method. A15 superconductors, which are produced by the powder-in-tube method, have the advantage that they can have the highest critical current densities. Consequently, the superconductors produced according to the powder-in-tube method are suitable for use in highly compacted and inexpensive magnetic systems.

The high current density and the high magnetic fields generated on this account, however, lead to increasing Lorentz forces in the magnet winding. These Lorentz forces can reduce the current carrying capacity of the superconducting wire of the magnet winding and therefore limit the area of application of the powder-in-tube wire.

### SUMMARY

A mechanically reinforced superconductor based on powder-in-tube can be provided which is also suitable for compact magnet systems. According to an embodiment, a method for production of a reinforced multifilament superconductor, may have the following steps: Preparation of several superconductor rods, each of which has at least one powder metallurgical core made from the elements of a metallic superconductor, in which the core is enclosed by an inner shell from a non-superconducting metal or a non-superconducting alloy; Preparation of an outer shell from a non-superconducting metal or a non-superconducting alloy, in which the outer shell has at least one reinforcement element made of tantalum or a tantalum alloy; Arrangement of the superconductor rods into a bundle; Enclosure of the bundle with the outer shell; Chipless machining of the enclosed bundle with reduction of the cross-section of the enclosed bundle to produce a multifilament; and Annealing of the deformed multifilament at a temperature and a sufficient period of time, so that superconducting phases are formed in the powder metallurgical core.

According to a further embodiment, the reinforcement element may have the shape of a shell tube. According to a further embodiment, the outer shell may have an outer shell tube made of a non-superconducting metal or a non-superconducting alloy and a reinforcement shell tube made of tantalum or a tantalum alloy, the outer shell tube enclosing the reinforcement shell tube. According to a further embodiment, the outer shell also may have an inner shell tube made of a non-superconducting metal or a non-superconducting alloy, the reinforcement shell tube closing the inner shell tube. According to a further embodiment, According to a further embodiment, the outer shell may be produced by hydrostatic extrusion. According to a further embodiment, for production of the outer shell, a pin may be hydrostatically extruded, and then the core drilled out. According to a further embodiment, the outer shell may have copper. According to a further embodiment, the percentage of reinforcement element may lie between about 10% and about 25% of the total multifilament. According to a further embodiment, the powder metallurgical core may be a core of the superconductor rods, each has the components of an A15 superconductor. According to a further embodiment, the powder metallurgical core of the superconductor rods each may have powders of NbTa, Nb₂Sn and Sn. According to a further embodiment, annealing may be carried out at 500° C. to 700° C. for 2 to 20 days. According to a further embodiment, the superconductor rods may be produced by a powder-in-tube method. According to a further embodiment, by chipless machining of the enclosed bundle, the multifilament may be produced in the form of a wire or the form of a strip.

According to another embodiment, a multifilament superconductor may comprise a core area, several superconductor filaments, the superconductor filaments each having a core made of a powder metallurgically produced superconductor, in which the core area is enclosed by an outer shell made of a non-superconducting metal or a non-superconducting alloy,

wherein the outer shell has at least one reinforcement element made of tantalum or a tantalum alloy.

According to a further embodiment, the multifilament may have the shape of a wire or strip. According to a further embodiment, the reinforcement element may have the shape of a shell tube. According to a further embodiment, the outer shell may have an outer shell tube made of a non-superconducting metal or a non-superconductor alloy and a reinforcement shell tube made of tantalum or a tantalum alloy, in which the outer shell tube encloses the reinforcement shell tube. According to a further embodiment, the outer shell also may have an inner shell tube made of a non-superconducting metal or a non-superconducting alloy, the reinforcement shell tube enclosing the initial tube. According to a further embodiment, the outer shell may have copper. According to a further embodiment, the percentage of reinforcement element may lie between about 10% and about 25% of the total multifilament. According to a further embodiment, the cores of the superconductor filaments each may have the components of an A15 superconductor. According to a further embodiment, the cores of the superconductor filaments each may have (Nb,Ta)₃Sn or NB₃Sn or Nb₃Al or Nb₃Si or Nb₃Ge or V₃S₁ or V₃Ga.

### BRIEF DESCRIPTION OF THE DRAWINGS

The invention is now further explained by means of the accompanying FIGURE.

FIG. 1 shows a reinforced multifilament superconductor.

### DETAILED DESCRIPTION

A method for production of a reinforced multifilament superconductor has the following steps: several superconductor rods are prepared, each of which has at least one powder metallurgical core from the elements of a metal superconductor. The core is enclosed by an inner shell of a non-superconducting metal or non-superconducting alloy. An outer shell of a non-superconducting metal or a non-superconducting alloy is prepared. The outer shell has at least one reinforcement element made of tantalum or a tantalum alloy. The superconducting rods are arranged in a bundle and the bundle enclosed with the outer shell. To produce a multifilament superconductor, the enclosed bundle is subjected to chipless machining with reduction of the cross-section of the enclosed bundle. The deformed multifilament is then annealed at a temperature and for a sufficient period of time, so that superconducting phases are formed in the powder metallurgical cores.

Reinforcement element in this context is to be understood to mean an object that is physically separated from the outer shell. The reinforcement element also consists of a composition other than that of the outer shell. An alloy additive or additives of the material of the outer shells is not prescribed.

A mechanically reinforced multifilament superconductor is produced by this method with a powder metallurgical process. The reinforcement element of the outer shell provides mechanical reinforcement of the multifilament, so that the yield point of the multifilament is increased. Because of this, the current carrying capacity of the multifilament is increased during use, so that the areas of application of the multifilament superconductor produced by the powder metallurgical method are expanded.

The arrangement of the reinforcement element as part of the outer shell has the advantage that in the ordinary production method, mechanical reinforcement of the multifilament can occur by preparing the outer shell with at least one reinforcement element. The reinforcement element, in one variant without alloy additives, is prescribed for mechanical reinforcement of the outer shell.

The cross-section of the enclosed bundle can be reduced by ordinary chipless machining methods, in which the length is simultaneously increased, so that an elongated multifilament is produced from the bundled rods. The cross-section can be reduced by methods, like drawing and hammering, optionally with intermediate annealings. The filaments of the multifilament essentially retain the arrangement of the rods of the bundle. In cross-section, the multifilament can have a regular two-dimensional matrix of superconductor filaments. The packing density is increased by the fact that the current carrying capacity of the multifilament is increased. In this context, the cross-section describes the cross-section perpendicular to the length of the multifilament and perpendicular to the length of the rods.

One or more reinforcement elements made of tantalum or a tantalum alloy have the advantage that they can be integrated with the other components of the multifilament based on their favorable deformation resistance. The other components of the multifilament are then the superconductor filaments and the outer shell. At the same time, tantalum is a metal that maintains its high mechanical properties under typical reaction conditions and during treatment to form the superconductor phase. Tantalum also has an extremely high E-modulus after heat treatment at the typical use temperatures in a range from 1.8 K to 10 K.

By chipless machining of the enclosed bundle, a multifilament with the configuration of a wire or the configuration of a strip can be produced.

In one variant, the reinforcement element is prepared in the form of a shell tube. This form can be used simply in known production methods. In another variant, the outer shell has an outer shell tube made of a non-superconducting metal or a non-superconducting alloy and a reinforcement shell tube made of tantalum or a tantalum alloy, the outer shell tube enclosing the reinforcement shell tube. Shell tube is not to be understood to mean merely a tube with a circular cross-section, but with any shape of the cross-section.

This arrangement has the advantage that the outermost surface of the multifilament can consist of an ordinary material. Consequently, the usual electrical connections can be made to the multifilament. For example, the outer surface remains wettable by solder. A mechanically reinforced multifilament superconductor is therefore provided that requires no additional changes during its use.

In another variant, the outer shell has an inner shell tube and an outer shell tube made of a non-superconducting metal or a non-superconducting alloy. The reinforcement shell tube encloses the inner shell tube and the outer shell tube and closes the reinforcement shell tube. The outer shell in this variant consists of three concentrically arranged shell tubes, the reinforcement shell tube being arranged between the inner shell tube and the outer shell tube.

The inner and outer tubes can have the same material or different materials. In one variant, the outer shell consists of copper. In another variant, the inner and outer tubes have copper and consist essentially of copper.

This arrangement has the advantage that the material of the innermost surface of the outer shell can consist of the ordinary material. This avoids undesired chemical reactions between the superconductor filaments and the outer shell and/or the reinforcement element. The current carrying capacity of the multifilament is therefore not adversely affected by the reinforcement element.

In one variant, the outer shell is produced by hydrostatic extrusion. Extrusion permits a good connection between the reinforcement element and the outer shell or the inner and outer shell tubes of the outer shell.

To produce the outer shell, a pin is hydrostatically extruded in one variant, and the core then drilled out, in order to provide a tube. This method provides good connection between the material of the reinforcement element and the different material of the outer shell. The superconductor rods can be packed as a bundle into the hole.

The superconductor rods can each have essentially the same cross-sectional surface. This simplifies formation of the bundle and formation of a regular two-dimensional matrix. In another variant, the superconductor rods are each provided with a hexagonal cross-section. A hexagonal cross-section permits tight packing of the rods in the matrix, so that the current carrying capacity of the multifilament can be increased.

The percentage of reinforcement elements can lie between about 10% and about 25% of the total number of rods of the matrix. This percentage can be adapted to the mechanical properties of the multifilament that are essential for a specific magnet system.

The percentage of reinforcement elements can be adjusted, for example, by the wall thickness of a single reinforcement shell tube or by the number of reinforcement shell tubes. In one variant, the outer shell has several reinforcement shell tubes that are separated from each other by non-superconducting metals or alloys. If, for example, two reinforcement shell tubes are provided, the outer shell has a total of five tubes.

The mechanical properties of the multifilament can be simply adjusted, so that a multifilament with the desired mechanical reinforcement can be provided. The mechanical properties can therefore be easily adjusted to the special requirement profile of the application.

The powder metallurgical cores of the superconductor rods can each have the components of an A15 superconductor. The powder metallurgical cores of the superconductor rods can also have powder from NbTa, Nb₂Sn and Sn, the superconducting phase (Nb, Ta)₃Sn being formed from these components.

The superconductor rods can be produced by a powder-in-tube method, in which powders of the desired components are shaped into a core or rod that is enclosed with a shell of non-superconducting metal or non-superconducting alloy. This preliminary product is optionally deformed with intermediate annealings, the cross-section being reduced and the length increased, in order to produce the superconductor rods. These superconductor rods are arranged into a bundle and enclosed with the outer shell.

The superconducting phase is only produced after bundling and after the additional deformation steps to produce the multifilament in the cores. For formation of the superconducting phases in the cores of the superconductor filaments, annealing of the multifilament can be carried out at 500° C. to 700° for 2 to 20 days.

The multifilament superconductor has a core area, having several superconductor filaments. The superconductor filaments each have a core made from a powder metallurgically produced superconductor. The core area is enclosed by an outer shell made of a non-superconducting metal or a non-superconducting alloy. The outer shell has at least one reinforcement element made of tantalum or a tantalum alloy.

As mentioned above, a reinforcement element is understood to mean an object that is separated from the outer shell and consists of a different composition than the outer shell. An alloy additive or alloy additives of the material of the outer shell are therefore ruled out with this term.

The multifilament is therefore mechanically reinforced based on the reinforcement element of the outer shell and can have the configuration of a wire or the configuration of a strip.

In one variant, the reinforcement element has the shape of a shell tube. In another variant, the outer shell has an outer shell tube made of a non-superconducting metal or a non-superconducting alloy and a reinforcement shell tube made of tantalum or a tantalum alloy, the outer shell tube enclosing the reinforcement shell tube.

In another variant, the outer shell has an inner shell tube, as well as an outer shell tube, made of a non-superconducting metal or a non-superconducting alloy. The reinforcement shell tube encloses the inner shell tube and the outer shell tube encloses the reinforcement shell tube, the reinforcement shell tube being arranged between the inner shell tube and the outer shell tube. The three shell tubes are arranged concentrically in one variant.

The outer shell can have copper or essentially consist of copper. If an inner shell tube and an outer shell tube are provided, these can consist of the same material or from different materials. In one variant, the inner shell tube and/or the outer shell tube has copper or consist essentially of copper.

The percentage of reinforcement elements can be adjusted and adapted to the requirement of the application. The percentage of reinforcement elements can lie between about 10% and about 25% of the total multifilament. The percentage, for example, can be adjusted by the wall thickness of the reinforcement element. Two or more reinforcement elements can also be provided and, in one variant, two reinforcement shell tubes are provided, which can be arranged concentrically in the outer shell. A non-superconducting metal shell tube or a non-superconducting alloy shell tube can be arranged between the corresponding reinforcement shell tubes. This arrangement permits an increase in reinforcement percentage when the reinforcement shell tubes are present with only a narrow wall thickness.

In one variant, the cores of the superconductor filaments each have the components of an A15 superconductor. The cores of the superconductor filaments can each have the components of the (Nb,Ta)₃Sn or Nb₃Sn or Nb₃Al or Nb₃Si or Nb₃Ge or V₃S₁ or V₃Ga phase or the superconducting (Nb,Ta)₃Sn or Nb₃Sn or Nb₃Al or Nb₃Si or Nb₃Ge or V₃S₁ or V₃Ga phase.

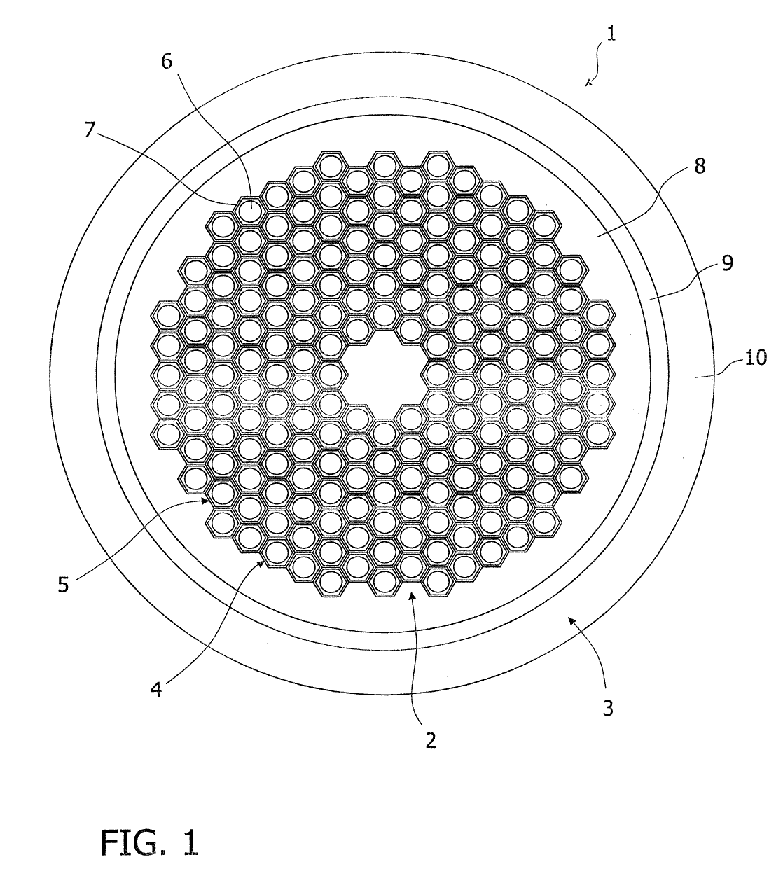

FIG. 1 shows the cross-section of a mechanically reinforced multifilament superconductor 1 with a core area 2 enclosed by an outer shell 3. The core area 2 has 192 superconductor filaments 4. The superconductor filaments 4 each have a hexagonal cross-sectional area, which is roughly equal for each filament. The superconductor filaments 4 are combined, in order to form a regular two-dimensional hexagonal matrix 5. The outer superconductor filaments 4 and matrix 5 are arranged, so that the outer edge of matrix 5 has an almost circular cross-section. In this variant, the inner central area of the core area has no superconductor filaments 4, but instead copper.

The superconductor filaments 4 each have a core 6 made of a powder metallurgical superconductor. The superconducting phase is (Nb,Ta)₃Sn. The core 6 is enclosed by an inner shell 7 made of copper. The superconductor filaments 4 were produced by a powder-in-tube method.

The outer shell 3 in this practical example consists of three concentrically arranged shell tubes. The inner shell tube 8 consists essentially of copper and encloses the core area of multifilament 1. The middle shell tube 9 consists essentially of tantalum and provides the mechanical reinforcement of the outer shell 3, as well as the entire multifilament 1. The outer shell tube 10 consists essentially of copper and encloses the reinforcement tube 9. The reinforcement tube 9 is therefore arranged directly between the inner shell tube 8 and the outer shell tube 10.

A reinforcement shell tube 9 made of tantalum has the advantage that tantalum can be easily deformed and processed during production, but after annealing to form the superconducting phase, still has a high E-modulus. Consequently, tantalum causes mechanical reinforcement of the end product and multifilament even during use at low temperatures, like 4 K.

To produce the multifilament 1, several superconductor rods were initially produced. To produce the superconductor rods, powders of the components of the superconducting phase NbTa, Nb₂Sn and Sn were shaped into a rod and enclosed with a copper shell. The cross-section was reduced by drawing, in order to form hexagonal superconductor rods.

The outer shell 3 was prepared by hydrostatic extrusion of a pin. A copper rod was enclosed by a tantalum shell tube and the tantalum tube by an outer shell tube made of copper. The composite was hydrostatically extruded, in order to improve the connection between the three parts. The core of the copper rod was then drilled out, in order to form the outer shell 3.

In one practical example, the outer shell has an outside diameter of 57.5 mm and an inside diameter of 44.6 mm, before deformation to form the multifilament. The tantalum shell tube has an inside diameter of 41 mm and, consequently, a wall thickness of 3.6 mm. The diameter of the hole was 37 mm.

The long sides of the superconductor rods were combined and arranged into a bundle, having a regular hexagonal matrix in cross-section. The bundle was enclosed with an outer shell and the enclosed bundle deformed by drawing and intermediate annealings, so that the cross-section is reduced, the length increased and a multifilament 1 produced. The arrangement of superconductor filaments 4 in matrix 5 of the produced multifilament 1 corresponds to the arrangement of the rods in the bundle. The multifilament 1 was then annealed at 500° C. to 700° C. for 2 to 20 days, so that the superconducting phase (Nb, Ta)₃Sn formed from the powder in the powder metallurgical cords 8.

In another not depicted practical example, an outer shell of two concentrically arranged shell tubes was produced. An inner shell tube made of tantalum was enclosed by an outer shell tube made of copper. The outside diameter of the outer shell tube was 65 mm, the hole had a diameter of 47 mm to 48 mm and the length of the outer shell was 1000 mm. This outer shell was used as the shell tube of the bundle as already described above.

Multifilament 1 can be used to produce a magnet winding. The multifilament 1 is mechanically reinforced by the reinforcement shell tube 6, so that the yield point of the multifilament 1 is increased. This leads to improved current carrying capacity, since the effect of the Lorentz force is reduced. This mechanically reinforced powder-in-tube multifilament can therefore be used in magnet systems, in which higher Lorentz forces occur and therefore the size of the magnet can be reduced, because of the higher current carrying capacity of the powder-in-tube multifilament. The area of application of this mechanically reinforced multifilament superconductor with powder metallurgical cores is therefore broadened.

### LIST OF REFERENCE NUMBERS

1 Multifilament
2 Core area
3 Outer shell
4 Superconductor filament
5 Matrix
6 Core of the superconductor filament
7 Inner shell of the superconductor filament
8 Inner shell tube
9 Reinforcement shell tube
10 Outer shell tube

What is claimed is:

1. A method for production of a reinforced multifilament superconductor, having the following steps:
Preparation of several superconductor rods, each of which has at least one powder metallurgical core made from the elements of a metallic superconductor, in which the core is enclosed by an inner shell from a non-superconducting metal or a non-superconducting alloy,
Preparation of an outer shell from a non-superconducting metal or a non-superconducting alloy, in which the outer shell has at least one reinforcement element made of tantalum or a tantalum alloy,
Arrangement of the superconductor rods into a bundle,
Enclosure of the bundle with the outer shell,
Chipless machining of the enclosed bundle with reduction of the cross-section of the enclosed bundle to produce a multifilament, and
Annealing of the deformed multifilament at a temperature and a sufficient period of time, so that superconducting phases are formed in the powder metallurgical core.

2. The method according to claim 1, wherein the reinforcement element has the shape of a shell tube.

3. The method according to claim 1, wherein the outer shell has an outer shell tube made of a non-superconducting metal or a non-superconducting alloy and a reinforcement shell tube made of tantalum or a tantalum alloy, the outer shell tube enclosing the reinforcement shell tube.

4. The method according to claim 3, wherein the outer shell also has an inner shell tube made of a non-superconducting metal or a non-superconducting alloy, the reinforcement shell tube closing the inner shell tube.

5. The method according to claim 1, wherein the outer shell is produced by hydrostatic extrusion.

6. The method according to claim 5, wherein for production of the outer shell, a pin is hydrostatically extruded, and then the core drilled out.

7. The method according to claim 1, wherein the outer shell has copper.

8. The method according to claim 1, wherein the percentage of reinforcement element lies between about 10% and about 25% of the total multifilament.

9. The method according to claim 1, wherein the powder metallurgical core is a core of the superconductor rods, each has the components of an A15 superconductor.

10. The method according to claim 1, wherein the powder metallurgical core of the superconductor rods each have powders of NbTa, Nb₂Sn and Sn.

11. The method according to claim 1, wherein annealing is carried out at 500° C. to 700° C. for 2 to 20 days.

12. The method according to claim 1, wherein the superconductor rods are produced by a powder-in-tube method.

13. The method according to claim 1, wherein by chipless machining of the enclosed bundle, the multifilament is produced in the form of a wire or the form of a strip.

14. A multifilament superconductor comprising a core area, several superconductor filaments, the superconductor filaments each having a core made of a powder metallurgically produced superconductor, in which the core area is enclosed by an outer shell made of a non-superconducting metal or a non-superconducting alloy, wherein the outer shell has at least one reinforcement element made of tantalum or a tantalum alloy.

15. The multifilament superconductor according to claim 14, wherein the multifilament has the shape of a wire or strip.

16. The multifilament superconductor according to claim 14, wherein the reinforcement element has the shape of a shell tube.

17. The multifilament superconductor according to claim 14, wherein the outer shell has an outer shell tube made of a non-superconducting metal or a non-superconductor alloy and a reinforcement shell tube made of tantalum or a tantalum alloy, in which the outer shell tube encloses the reinforcement shell tube.

18. The multifilament superconductor according to claim 14, wherein the outer shell also has an inner shell tube made of a non-superconducting metal or a non-superconducting alloy, the reinforcement shell tube enclosing the initial tube.

19. The multifilament superconductor according to claim 14, wherein the outer shell has copper.

20. The multifilament superconductor according to claim 14, wherein the percentage of reinforcement element lies between about 10% and about 25% of the total multifilament.

21. The multifilament superconductor according to claim 14, wherein the cores of the superconductor filaments each have the components of an A15 superconductor.

22. The multifilament superconductor according to claim 21, wherein the cores of the superconductor filaments each have (Nb,Ta)₃Sn or NB₃Sn or Nb₃Al or Nb₃Si or Nb₃Ge or V₃S₁ or V₃Ga.
